(19) United States
(12) Patent Application Publication
(10) Pub. No.: US 2025/0323172 A1
(43) Pub. Date: Oct. 16, 2025

(54) SEMICONDUCTOR STRUCTURE AND METHOD OF MANUFACTURING THE SAME

(71) Applicant: Fujian Jinhua Integrated Circuit Co., Ltd., Quanzhou City (CN)

(72) Inventors: Yue Liu, Quanzhou City (CN); Lichen Liu, Quanzhou City (CN); Chung-Ping Hsia, Quanzhou City (CN)

(73) Assignee: Fujian Jinhua Integrated Circuit Co., Ltd., Quanzhou City (CN)

(21) Appl. No.: 18/814,581

(22) Filed: Aug. 25, 2024

(30) Foreign Application Priority Data
Apr. 11, 2024 (CN) 202410438003.7

(51) Int. Cl. H01L 23/544; H01L 21/027; H01L 21/311

(52) U.S. Cl. CPC H01L 23/544; H01L 21/0274; H01L 21/31144; H01L 2223/54426

(57) ABSTRACT

A semiconductor structure is provided in the present invention, including a substrate, a recess in the substrate, an alignment mark in the recess, and a gate pattern on the alignment mark and including a metal layer, wherein a top plane of the metal layer is lower than a top plane of the recess.

### BACKGROUND OF THE INVENTION

### 1. Field of the Invention

The present invention relates generally to a semiconductor structure and method of manufacturing the same, more specifically, to a semiconductor structure with alignment marks and method of manufacturing the same.

### 2. Description of the Prior Art

In the manufacturing process of modern integrated circuits, different mask patterns need to be overlapped on a wafer. There might be more than dozens of times of mask overlapping steps being performed depending on processes and technologies. Photolithography process is exactly the process of forming those masks in semiconductor manufacture. In order to ensure follow-up semiconductor patterns are formed on correct relative positions with respect to the patterns in pre-layers, mask patterns in every layer should be overlapped precisely with the ones of pre-layer, which may be referred as overlay, representing an overlapping quality of the layer formed in preceding photolithography process and the layer in instant photolithography process.

Existing overlay inspection method determines overlay quality of two successive photolithographic levels mainly through specific overlay marks (or referred as alignment marks). The overlay marks utilized in the measurement of overlay testing tools is usually composed of rectangular or square patterns. The overlay patterns are designed in the two photolithographic levels, wherein smaller overlay pattern may be designedly fitted right into larger overlay pattern, and relevant overlay values may be obtained by calculating the distance between corresponding edges of the two patterns.

### SUMMARY OF THE INVENTION

The present invention provides a semiconductor structure with alignment mark and method of manufacturing the same, featuring special gate patterns on the formed alignment marks.

One aspect of the present invention is to provide a semiconductor structure, including: a substrate; a recess in the substrate; an alignment mark in the recess; and a gate pattern on the alignment mark, and the gate pattern includes a metal layer, wherein a top plane of the metal layer is lower than a top plane of the recess.

Another aspect of the present invention is to provide a method of manufacturing a semiconductor structure, including: forming a recess on a substrate; forming a dielectric layer on the substrate, the dielectric layer fills up the recess; performing an etchback process to the dielectric layer to form an alignment mark in the recess; forming a gate material layer and a photolithography material layer on the alignment mark, and the gate material layer includes a metal layer; performing a photolithography process to pattern the photolithographic material layer to form a photolithographic material pattern; and performing an etching process using the photolithographic material pattern as a mask to pattern the photolithographic material layer into gate patterns, wherein a top plane of the metal layer in the gate patterns is lower than a top plane of the recess.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute a part of this specification. The drawings illustrate some of the embodiments and, together with the description, serve to explain their principles. In the drawings:

FIGS. 1-4 are schematic cross-sections illustrating a process flow of a semiconductor device with alignment mark in accordance with one embodiment of present invention;

FIG. 5 is a schematic top view of a semiconductor device with alignment mark in accordance with one embodiment of present invention; and

FIG. 6 is a schematic cross-section of a semiconductor device with alignment mark in accordance with another embodiment of present invention.

### DETAILED DESCRIPTION

Reference now be made in detail to exemplary embodiments of the invention, which are illustrated in the accompanying drawings in order to understand and implement the present disclosure and to realize the technical effect. It can be understood that the following description has been made only by way of example, but not to limit the present disclosure. Various embodiments of the present disclosure and various features in the embodiments that are not conflicted with each other can be combined and rearranged in various ways. Without departing from the spirit and scope of present disclosure, modifications, equivalents, or improvements to the present disclosure are understandable to those skilled in the art and are intended to be encompassed within the scope of the present disclosure.

In the specification, each figure is divided into a left picture and a right picture, representing respectively the pattern formations on different alignment marks on the same substrate. Evolution of the two different formations will be illustrated in the embodiment in order to provide a clear understanding to the present invention for readers.

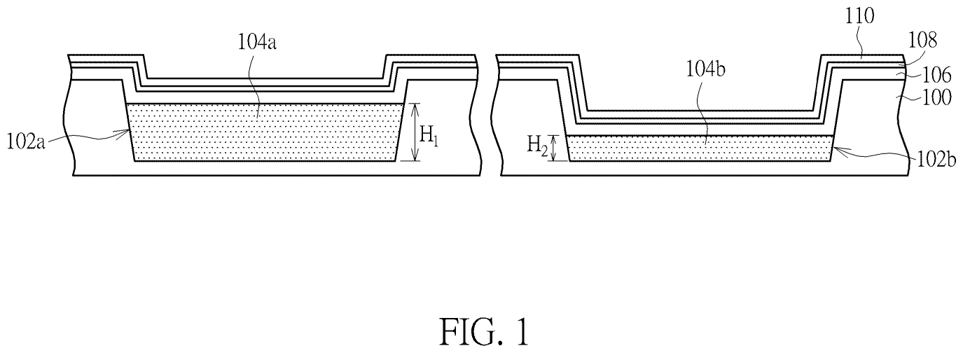

First, please refer to FIG. 1. The semiconductor structure of present invention is manufactured on a semiconductor substrate 100, such as silicon (Si) substrate, germanium (Ge) substrate or silicon germanium (SiGe) substrate. In the embodiment, recesses 102a, 102b are formed on the substrate 100 with isolation material filling therein, so as to form the alignment marks 104a, 104b (or referred as overlay marks) in the semiconductor structure of present invention. The alignment mark 104a, 104b may be formed by first forming a dielectric layer filling up the recesses 102a, 102b on the substrate 100, then performing an etchback process to etch the dielectric layer. The material of the dielectric layer may be silicon oxide, silicon nitride or the multilayer thereof.

The alignment marks 104a, 104b of present invention may be positioned in the scribe lines of wafer, which is used to test overlapping quality of mask features and pre-layer features in the overlay step. The alignment marks 104 may also be formed together with structures in other regions in the same process. For example, the alignment marks 104 and shallow trench isolations (STIs) in cell region and/or peripheral region may be formed at the same time, more specifically, through the same photolithography process to form recesses and filling isolation material in the recesses to form the alignment marks 104a, 104b on the scribe line and the STIs on cell region, respectively. Please note that in the embodiment of present invention, the alignment marks 104a, 104b in left and right recesses 102a, 102b may have different heights. This may be resulted from different widths of the recesses 102a, 102b, since the alignment marks 104a, 104b formed in the same deposition process may be provided with different heights on the basic of the same recess depth. Take FIG. 1 for an example, the width of recess 102a is designedly smaller than the width of recess 102b, wherein the height H₁ of alignment mark 104a formed therein would be higher than the height H₂ of alignment mark 104b. In the present invention, the widths of recesses and the heights of alignment marks are also the cause of structural difference in the semiconductor structures formed thereon later.

Refer still to FIG. 1. After the alignment marks 104a, 104b are formed, gate material layers like a semiconductor layer 106, a metal layer 108 and a hard mask layer 110 are formed sequentially and conformally on the substrate 100 and alignment marks 104a, 104b. Similar to the alignment marks 104a, 104b, in the embodiment of present invention, the aforementioned layer structure and structures in other regions may be formed in the same process. For example, the semiconductor layer 106, metal layer 108 and hard mask layer 110 may be formed on the scribe line, cell region and/or peripheral region at the same time, through the same deposition process like chemical vapor deposition (CVD) or atomic layer deposition (ALD). The material of semiconductor layer 106 may be doped silicon, and the material of metal layer 108 may be metal nitride, ex. silicon nitride (Si₃N₄), tantalum nitride (TaN) and/or tungsten nitride (WN), or low-resistance metal like tungsten (W), aluminum (Al), titanium (Ti), tantalum (Ta) or the multilayer thereof. The material of hard mask layer 110 may be silicon nitride or silicon oxynitride (SiON). The semiconductor layer 106, metal layer 108 and hard mask layer 110 formed on cell region and peripheral region may serve as material layers for bit lines and the gate structure of peripheral circuit.

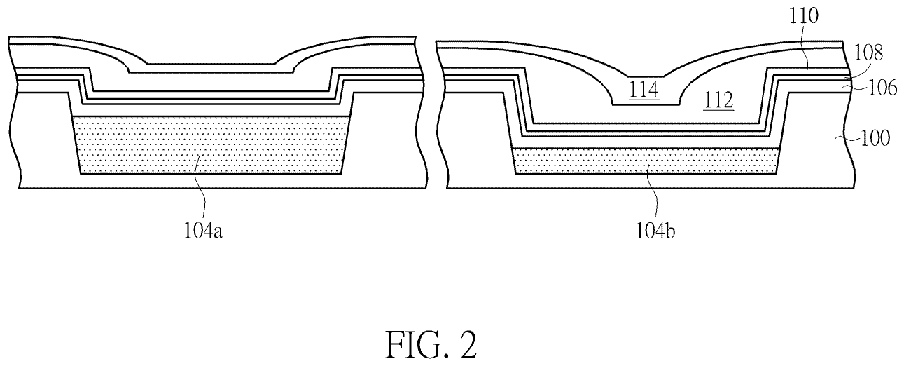

Please refer to FIG. 2. After the layer structure like alignment marks 104a, 104b, semiconductor layer 106, metal layer 108 and hard mask layer 110 are formed, a photolithographic material layer is formed on the hard mask layer 110. The photolithography material layer may include but not limited to Si-based anti-reflection coating (SiARC) 112 and bottom anti-reflection coating (BARC) 114. Please note that in the embodiment of present invention, since the aforementioned differences in the widths of recesses and in the heights of alignment marks, the thickness of BARC 114 and SiARC 112 formed on the alignment marks 104a, 104b in a direction vertical to substrate may also be different. Generally, the thickness of SiARC 112 formed on the alignment marks 104b may be larger than the thickness of SiARC 112 formed on the alignment marks 104a, and the closer to reflective sidewall of the recess, the larger the thickness of SiARC 112. In the embodiment of present invention, this thickness difference may result in different photolithographic patterns formed in the photolithography process later.

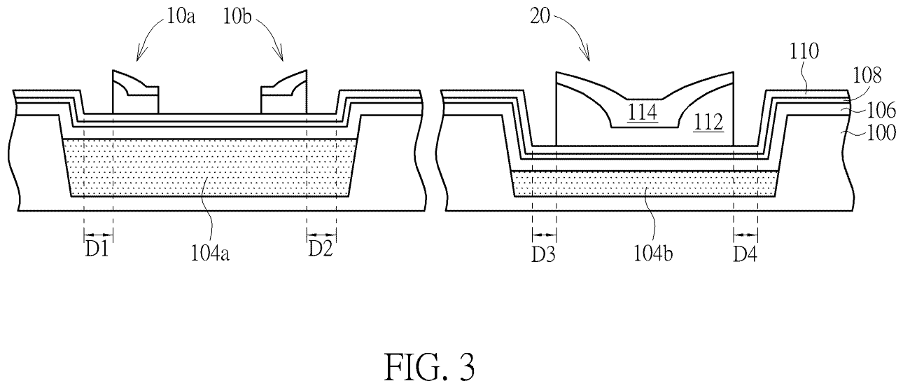

Please refer to FIG. 3. After the BARC 114 and SiARC 112 are formed, a photolithography process is then performed to pattern the BARC 114 and SiARC 112, so as to form required mask pattern. In the embodiment of present invention, specifically, the photolithography process may include forming a photoresist on the BARC 114, exposing the layer structures like the photoresist, BARC 114 and SiARC 112, and performing a development step to remove unnecessary parts in those layer structures to form photoresist pattern. In the embodiment of present invention, the formed photolithography pattern may be bit lines on cell region and/or gate patterns on peripheral region, which may be used as an etch mask in an etching process later to pattern the underlying layer structures like semiconductor layer 106, metal layer 108 and hard mask layer 110 into the structure like contacts of storage nodes and/or gates.

Please note that in the embodiment of present invention, the layer structure like semiconductor layer 106, metal layer 108 and hard mask layer 110 on the scribe line (i.e. the alignment mark region in the figure) are supposed to be removed. Therefore, it should be no photolithographic material like BARC 114 and SiARC 112 remaining on the alignment marks 104a, 104b after the aforementioned photolithography process. However, since the thickness of SiARC 112 formed on the alignment marks 104a, 104b is much larger than the ones in other regions, residues of SiARC 112 and BARC 114 may be likely to remain on the alignment marks 104a, 104b after the aforementioned exposure step due to incomplete exposure. As shown in FIG. 3, as far as the alignment mark 104a is concerned, the parts of SiARC 112 and BARC 114 close to recess sidewalls remain, so as to form photolithographic material patterns 10a, 10b separated from the recess sidewalls by a first distance D1 and a second distance D2, respectively. With respect to the alignment mark 104b, since the SiARC 112 thereon is thicker on the whole, not only the parts close to the recess sidewalls would remain, but the middle part also remains, so as to form a photolithographic material patterns 20 covering nearly entire alignment mark 104b, wherein the photolithographic patterns 20 are separated from the recess sidewalls at two sides by a third distance D3 and a fourth distance D4, respectively. In addition, since the BARC 114 and SiARC 112 near the recess sidewalls are subject to stronger exposure, they may be removed more easily in development step in spite of their larger thickness. The aforementioned residues of BARC 114 and SiARC 112 will be separated from the adjacent recess sidewalls by a certain distance without contacting therewith. The aforementioned photolithographic pattern that is not completely removed will result in the residue of layer structure like conductive layer 106, metal layer 108 and hard mask layer 110 on the alignment mark later.

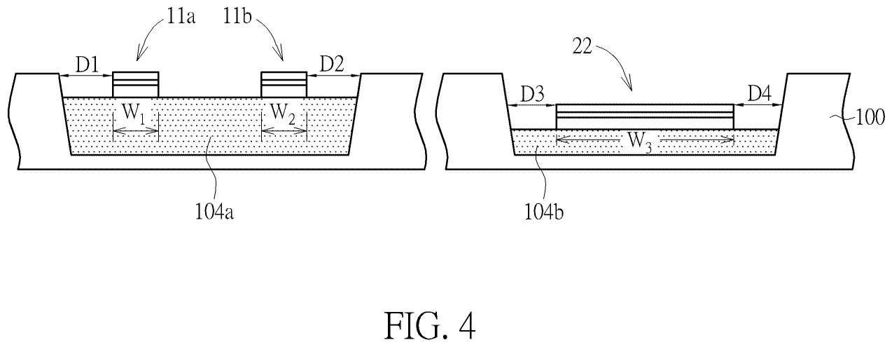

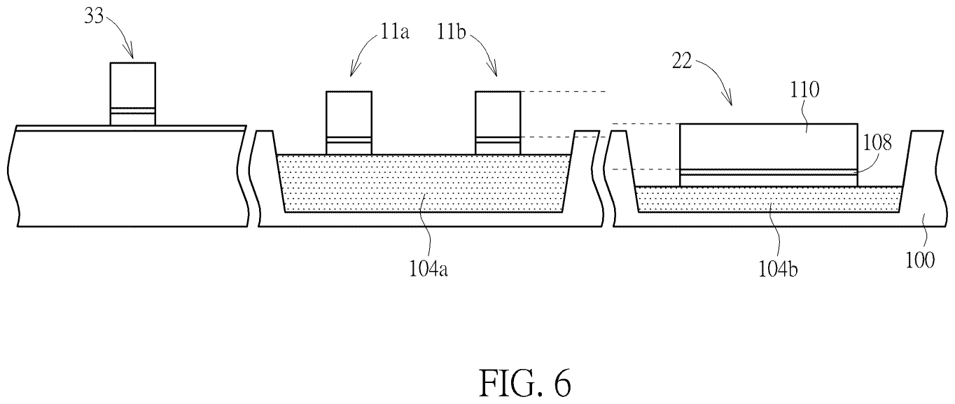

Please refer to FIG. 4. After the photolithography process, an etching process using the formed photolithographic material pattern (including 10a, 10b and 20) as an etch mask to pattern the underlying layer structure like the hard mask layer 110, metal layer 108 and conductive layer 106, so as to form bit lines on cell region and/or gates on peripheral region (as the gate 33 shown in FIG. 6). In the embodiment of present invention, since there are photolithographic material patterns 10a, 10b, 20 remaining on the alignment marks 104a, 104b, they will form corresponding gate patterns on the alignment marks 104a, 104b. As shown in FIG. 4, a first gate pattern consisting of a first part 11a and a second part 11b is formed on the alignment mark 104a, while a whole piece of second gate pattern 22 is formed on the alignment mark 104b. Please note that, similar to the photolithographic material patterns 10a, 10b, 20, the first part 11a and second part 11b of first gate pattern are close to the recess sidewalls at two sides respectively and are separated from the sidewalls by a first distance D1 and a second distance D2. The second gate pattern 22 covers nearly entire alignment mark 104b and are separated from the adjacent recess sidewalls at two sides by a third distance D3 and a fourth distance D4. Besides, the first part 11a and second part 11b of first gate pattern are provided respectively with a first width W₁ and a second width W₂, the second gate pattern is provided with a third width W₃, and the first width W₁ and the second width W₂ are both smaller than the third width W₃.

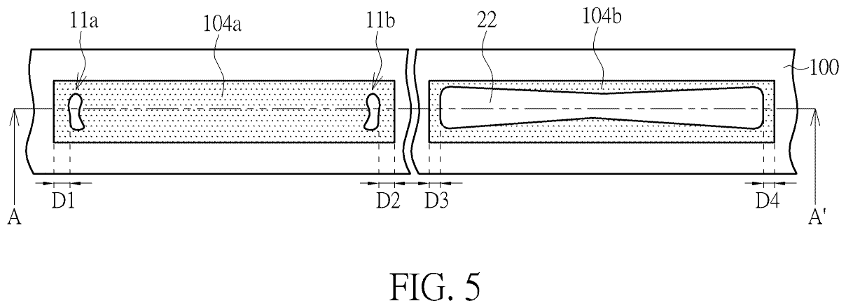

Please refer to FIG. 5, which is a schematic top view of the semiconductor structure with alignment mark as shown in aforementioned FIG. 4. As shown in the figure, the rectangular dark portion in the figure is the alignment marks 104a, 104b of present invention. As far as the left picture is concerned, a first part 11a and a second part 11b of the first gate pattern is provided on positions close to two ends of the alignment mark 104a in longitudinal direction. With respect to the right picture, the entire alignment mark 104b is nearly covered by the second gate pattern 22, and only the surrounding portion close to edges is not covered. It can be seen from the right picture that, since the portion close to middle is subject to stronger exposure, the width of resulting second gate pattern 22 is gradually reduced from two ends to middle in longitudinal direction.

Please refer to FIG. 6. In the embodiment of present invention, the metal layers 108 formed in the gate patterns 11a, 11b, 22 in recesses 102a, 102b would be lowered than the top plane of recesses 102a, 102b. On the other hand, in certain embodiment having thicker hard mask layer 110, the top plane of hard mask layer 110 in gate patterns 11a, 11b, 22 would be higher than the top plane of recesses 102a, 102b. The metal layer 108 of gate patterns 11a, 11b is higher than the metal layer 108 of gate pattern 22. Since the gate 33 on peripheral region is formed on the substrate 100 rather than in the recess, its layer structure would be higher than the one of gate patterns 11a, 11b.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A semiconductor structure, comprising:
a substrate;
a recess in said substrate;
an alignment mark in said recess; and
a gate pattern on said alignment mark, and said gate pattern comprises a metal layer;
wherein a top plane of said metal layer is lower than a top plane of said recess.

2. The semiconductor structure of claim 1, wherein said recess comprises a first recess and a second recess, and a top plane of said alignment mark in said first recess is higher than a top plane of said alignment mark in said second recess.

3. The semiconductor structure of claim 2, wherein said gate pattern comprises a first gate pattern on said first recess and a second gate pattern on said second recess.

4. The semiconductor structure of claim 3, wherein said first gate pattern on said first recess comprises a first part and a second part respectively at two ends of said alignment mark and separated respectively from sidewalls of said first recess by a first distance and a second distance.

5. The semiconductor structure of claim 4, wherein said first part and said second part have a first width and a second width respectively, and said second gate pattern has a third width, and said first width and said second width are both smaller than said third width.

6. The semiconductor structure of claim 4, wherein said second gate pattern on said second recess is in the middle of said alignment mark and separated from a sidewall of said second recess by a third distance.

7. The semiconductor structure of claim 6, wherein said third distance is smaller than said first distance and said second distance.

8. The semiconductor structure of claim 1, wherein said gate pattern further comprises a semiconductor layer and a hard mask layer, and said semiconductor layer, said metal layer and said hard mask layer stack sequentially on said alignment mark.

9. The semiconductor structure of claim 8, wherein a top plane of said hard mask layer is higher than said top plane of said recess.

10. A method of manufacturing a semiconductor structure, comprising:
forming a recess on a substrate;
forming a dielectric layer on said substrate, and said dielectric layer fills up said recess;
performing an etchback process to said dielectric layer to form an alignment mark in said recess;
forming a gate material layer and a photolithographic material layer on said alignment mark, and said gate material layer comprises a metal layer;
performing a photolithography process to pattern said photolithographic material layer to form a photolithographic material pattern; and
performing an etching process using said photolithographic material pattern as a mask to pattern said photolithographic material layer into a gate pattern, wherein a top plane of said metal layer in said gate pattern is lower than a top plane of said recess.

11. The method of manufacturing a semiconductor structure of claim 10, wherein said recess comprises a first recess and a second recess, and a top plane of said alignment mark in said first recess formed in said etchback process is higher than a top plane of said alignment mark in said second recess.

12. The method of manufacturing a semiconductor structure of claim 11, wherein said gate pattern comprises a first gate pattern on said first recess and a second gate pattern on said second recess.

13. The method of manufacturing a semiconductor structure of claim 12, wherein said first gate pattern on said first recess comprises a first part and a second part respectively at two ends of said alignment mark and separated respectively from sidewalls of said first recess by a first distance and a second distance.

14. The method of manufacturing a semiconductor structure of claim 13, wherein said first part and said second part have a first width and a second width respectively, and said second gate pattern has a third width, and said first width and said second width are both smaller than said third width.

15. The method of manufacturing a semiconductor structure of claim 13, wherein said second gate pattern on said second recess is in middle of said alignment mark and separated from a sidewall of said second recess by a third distance.

16. The method of manufacturing a semiconductor structure of claim 15, wherein said third distance is smaller than said first distance and said second distance.

17. The method of manufacturing a semiconductor structure of claim 10, wherein said gate material layer further comprises a semiconductor layer and a hard mask layer, and said semiconductor layer, said metal layer and said hard mask layer stack sequentially on said alignment mark, and a top plane of said hard mask layer in said gate material pattern is higher than said top plane of said recess.

18. The method of manufacturing a semiconductor structure of claim 10, wherein said etching process patterns said gate material layer into bit lines at the same time.
